(19) United States
(12) Patent Application Publication
(10) Pub. No.: US 2025/0244666 A1
(43) Pub. Date: Jul. 31, 2025

(54) RESIST COMPOSITION AND PATTERNING PROCESS

(71) Applicant: Shin-Etsu Chemical Co., Ltd., Tokyo (JP)

(72) Inventors: Shun Kikuchi, Joetsu-shi (JP); Satoshi Kusama, Joetsu-shi (JP); Ryunosuke Handa, Joetsu-shi (JP); Masaki Ohashi, Joetsu-shi (JP)

(73) Assignee: Shin-Etsu Chemical Co., Ltd., Tokyo (JP)

(21) Appl. No.: 19/035,087

(22) Filed: Jan. 23, 2025

(30) Foreign Application Priority Data
Jan. 31, 2024 (JP) 2024-013007

(51) Int. Cl. G03F 7/004; C08K 5/095; G03F 7/039; G03F 7/32

(52) U.S. Cl. CPC G03F 7/0046; C08K 5/095; G03F 7/0397; G03F 7/322

(57) ABSTRACT

The non-chemically-amplified resist composition exhibits a high sensitivity and maximum resolution when processed by photolithography using high-energy radiation, typically EB and EUV lithography. The resist composition comprises a hypervalent iodine compound, a carboxy-containing polymer, and a solvent is provided. When processed by photolithography using high-energy radiation, the resist composition exhibits a high sensitivity and resolution.

### CROSS-REFERENCE TO RELATED APPLICATIONS

This non-provisional application claims priority under 35 U.S.C. § 119 (a) on Patent Application No. 2024-013007 filed in Japan on Jan. 31, 2024, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable unsaturated bond. With respect to the patterning of a resist film to a feature size of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. Particularly in the case of line-and-space patterns, chances of collapse and disconnection of patterns increase outstandingly as the pattern size becomes smaller. Minimizing such chances leads to an improvement in maximum resolution.

Patent Document 2 discloses a negative resist composition comprising a tin compound. Based on tin element having high EUV absorption, this resist composition is improved in stochastics and achieves a high sensitivity and high resolution. The so-called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-005224 (U.S. Pat. No. 10,323,113)
Patent Document 2: JP-A 2021-503482
Non-Patent Document 1: SPIE Vol. 5039 p1 (2003)
Non-Patent Document 2: SPIE Vol. 6520 p65203L-1 (2007)

### SUMMARY OF THE INVENTION

An object of the invention is to provide a non-chemically-amplified resist composition which exhibits a high sensitivity and maximum resolution when processed by photolithography using high-energy radiation, typically EB and EUV lithography, and a patterning process using the same.

The inventors have found that a resist composition based on a hypervalent iodine compound and a polymer having a carboxy group and a specific cyclic structure has a very high sensitivity, forms a resist film having a satisfactory resolution, and is thus quite useful in precise micropatterning.

In one aspect, the invention provides a resist composition comprising a hypervalent iodine compound, a carboxy-containing polymer, and a solvent. The hypervalent iodine compound has the formula (1):

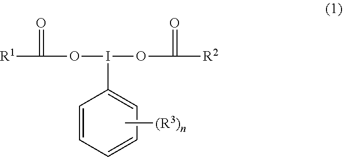

wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and the intervenient atoms, and
R³ is halogen or a C₁-C₄₀ hydrocarbyl group which may contain a heteroatom.

The carboxy-containing polymer comprises repeat units having the formula (2), and repeat units of at least one type selected from repeat units having the formula (3), repeat units having the formula (4), repeat units having the formula (5), repeat units having the formula (6), and repeat units having the formula (7):

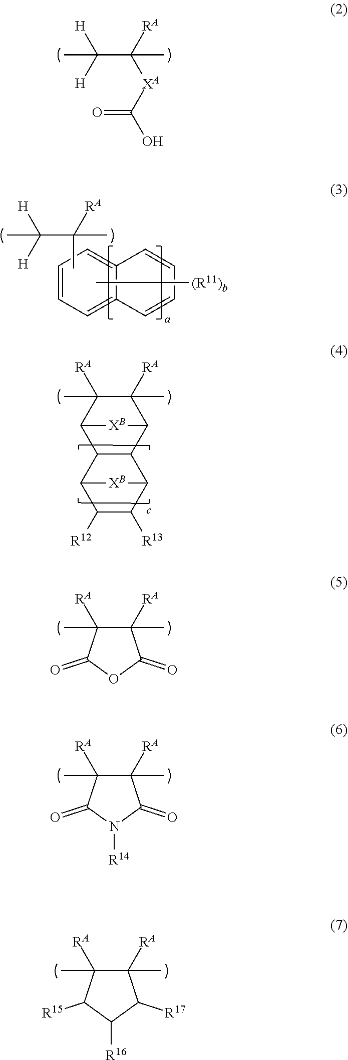

wherein a is an integer of 0 to 2, b is an integer meeting 0≤b≤5+2a, c is an integer of 0 to 2,
R^{A} is hydrogen, fluorine, methyl or trifluoromethyl,
X^{A} is a single bond, phenylene, naphthylene, or *—C(═O)—O—X^{A1}—, X^{A1} is a C₂-C₁₀ saturated hydrocarbylene group, phenylene group or naphthylene group, the saturated hydrocarbylene group may contain at least one moiety selected from hydroxy, ether bond, ester bond and lactone ring, * designates a point of attachment to the carbon atom in the backbone,
X^{B} is each independently —CH₂— or —O—,
R¹¹ is hydroxy, halogen, nitro, sulfo, carboxy, isocyanate, a C₁-C₂₀ hydrocarbyl group which may contain a heteroatom, —N(R^{11A})(R^{11B}), —P(R^{11C})(R^{11D}), —B(OR^{11E})(OR^{11F}), —O—R^{11G}, —C(═O)—O—R^{11G}, or —O—C(═O)—R^{11G}, R^{11A} and R^{11B} are each independently hydrogen or a C₁-C₂₀ hydrocarbyl group, R^{11C} and R^{11D} are each independently a C₁-C₂₀ hydrocarbyl group, R^{11E} and R^{11F} are each independently a C₁-C₂₀ hydrocarbyl group, R^{11E} and R^{11F} may bond together to form a ring with the boron atom to which they are attached, R^{11G} is each independently a C₁-C₂₀ hydrocarbyl group which may contain a heteroatom,
R¹², R¹³, and R¹⁵ to R¹⁷ are each independently hydrogen, halogen, or a C₁-C₂₀ hydrocarbyl group which may contain a heteroatom, R¹² and R¹³ may bond together to form a ring with the carbon atoms to which they are attached, and R¹⁵ and R¹⁶ and/or R¹⁶ and R¹⁷ may bond together to form a ring with the carbon atoms to which they are attached, and R¹⁴ is hydrogen or a C₁-C₂₀ hydrocarbyl group which may contain a heteroatom.

In another aspect, the invention provides a laminate comprising a substrate and a resist film formed thereon from the resist composition defined herein.

The laminate may further comprise an underlying film between the substrate and the resist film.

In a further aspect, the invention provides a pattern forming process comprising the steps of applying the resist composition defined herein onto a substrate or a substrate having an underlying film deposited thereon to form a resist film thereon, exposing the resist film to i-line, KrF excimer laser, ArF excimer laser, EB or EUV, and developing the exposed resist film in a developer.

Preferably, the developer is an organic solvent.

### Advantageous Effects of Invention

The resist composition exhibits both high sensitivity and resolution when processed by lithography using i-line, KrF excimer laser, ArF excimer laser, EB or EUV and is quite useful in micropatterning.

### DETAILED DESCRIPTION OF THE INVENTION

The terms “a” and “an” herein do not denote a limitation of quantity, but rather denote the presence of at least one of the referenced item. As used herein, the notation (Cₙ-Cₘ) means a group containing from n to m carbon atoms per group.

The abbreviations and acronyms have the following meaning.
UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### [Resist Composition]

One embodiment of the invention is a resist composition based on a hypervalent iodine compound and a carboxy-containing polymer.

### [Hypervalent Iodine Compound]

The hypervalent iodine compound is a three-coordinate hypervalent iodine compound having the formula (1).

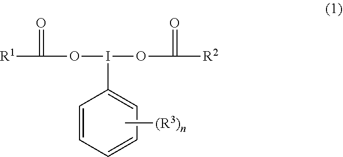

In formula (1), n is an integer of 0 to 5.

In formula (1), R¹ and R² are each independently halogen or a C₁-C₁₀ hydrocarbyl group which may contain a heteroatom. Also, R¹ and R² may bond together to form a ring with the carbon atoms to which they are attached and the intervenient atoms. Suitable halogen atoms include fluorine, chlorine, bromine and iodine. The C₁-C₁₀ hydrocarbyl group may be saturated or unsaturated and straight, branched or cyclic. Examples thereof include C₁-C₁₀ alkyl groups such as methyl, ethyl, n-propyl, isopropyl, n-butyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo [5.2.1.0^{2,6}]decanyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ and R² are preferably C₁-C₄ hydrocarbyl groups.

In formula (1), R³ is halogen or a C₁-C₄₀ hydrocarbyl group which may contain a heteroatom. When n is an integer of 2 to 5, a plurality of R³ may be the same or different. Suitable halogen atoms include fluorine, chlorine, bromine and iodine. The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo [5.2.1.0^{2,6}]decanyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

Examples of the hypervalent iodine compound having formula (1) are shown below, but not limited thereto.

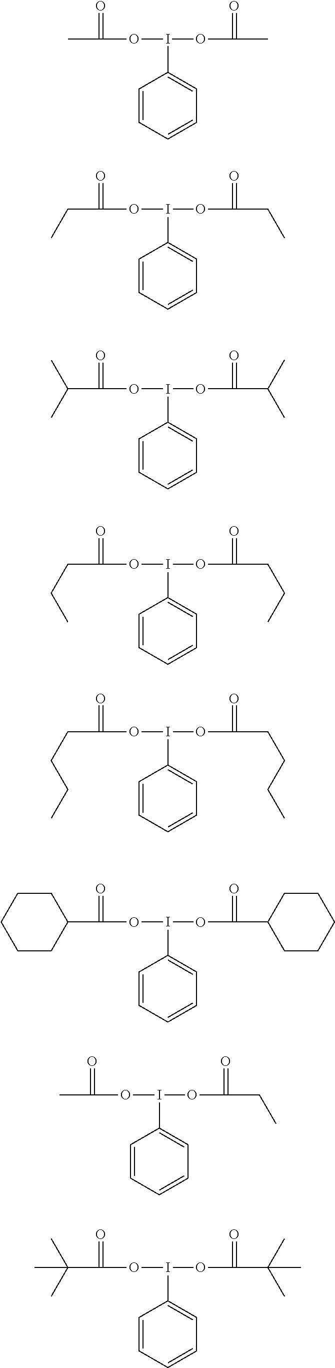

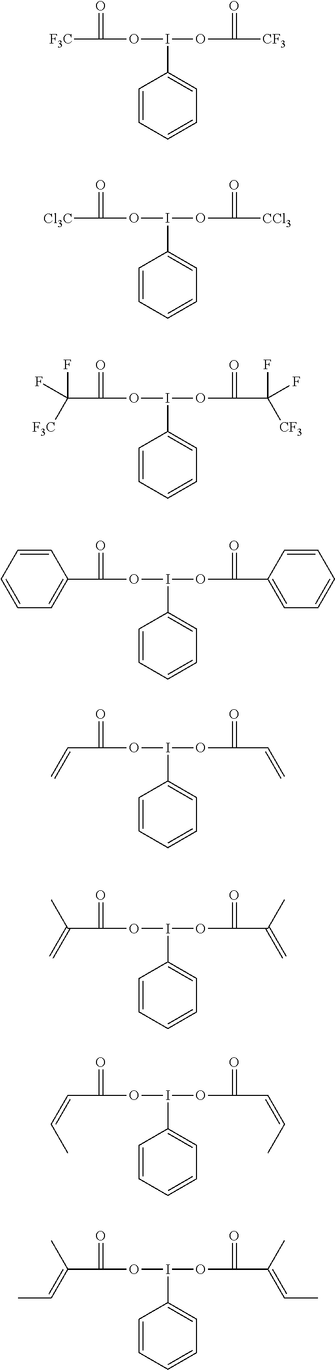

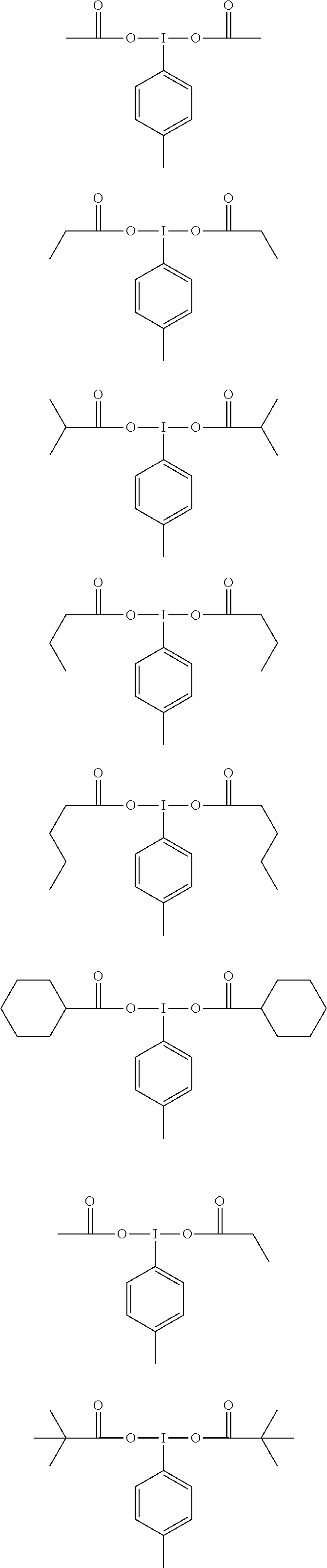

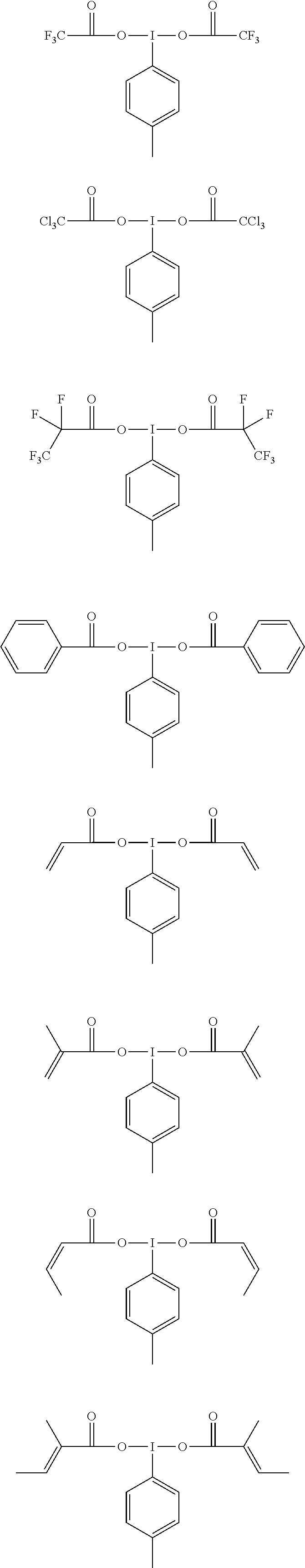

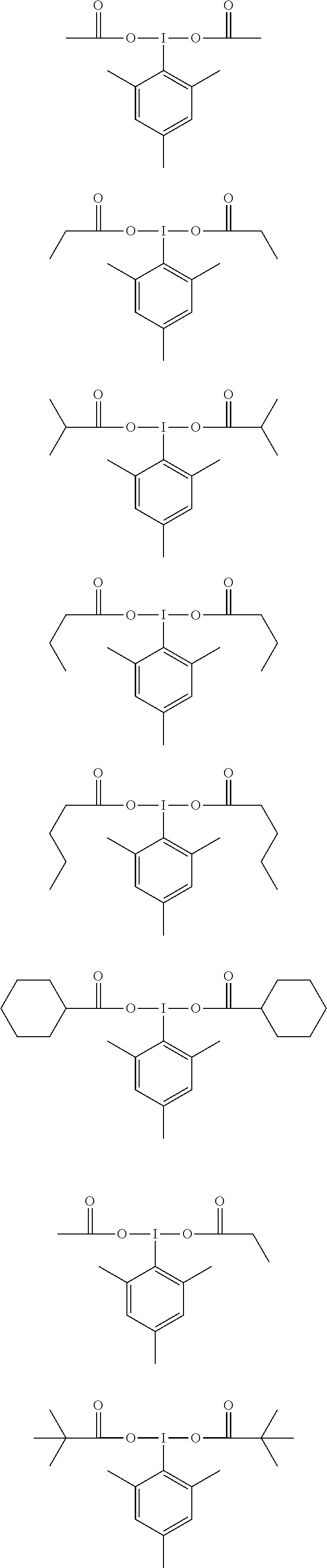

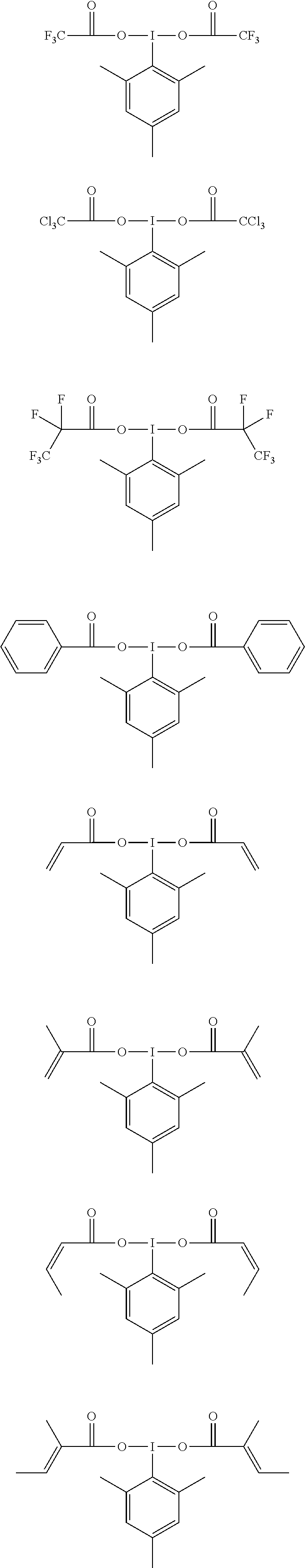

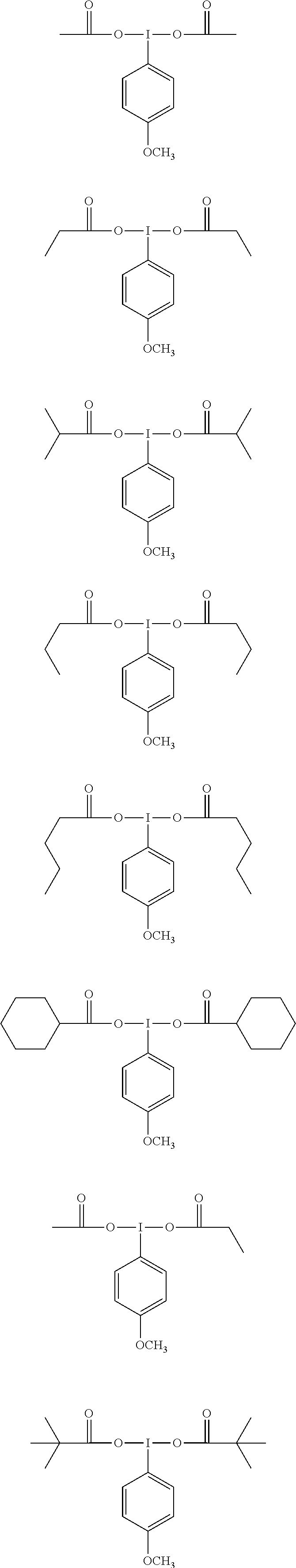

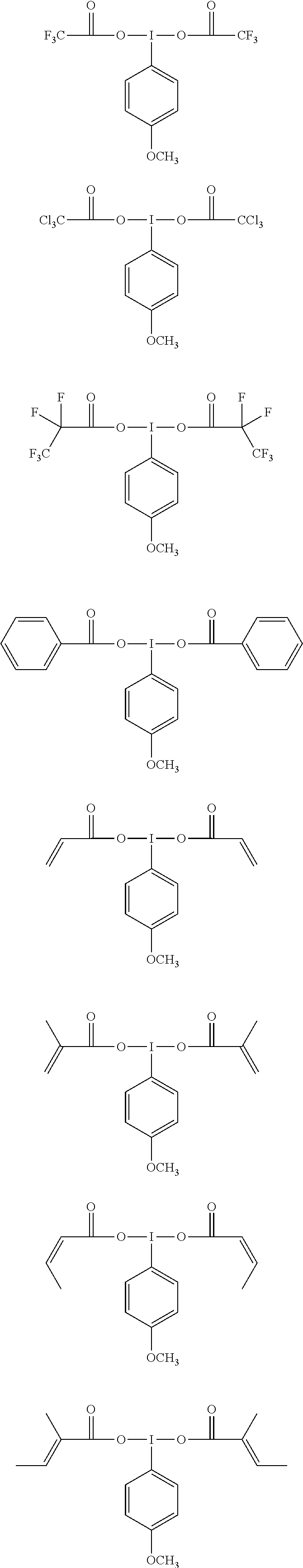

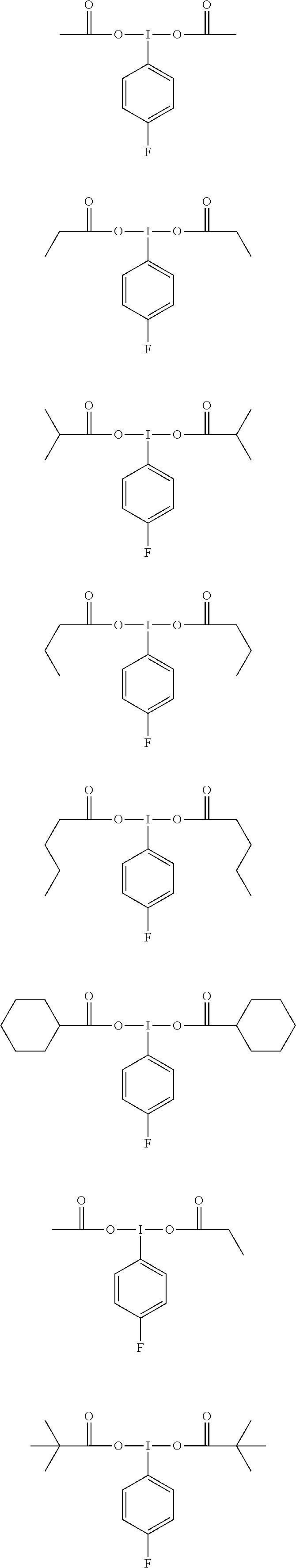

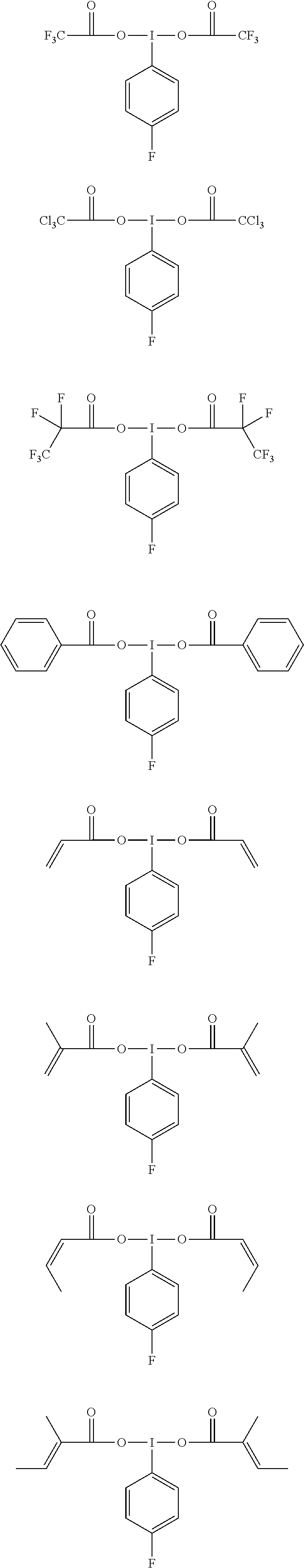

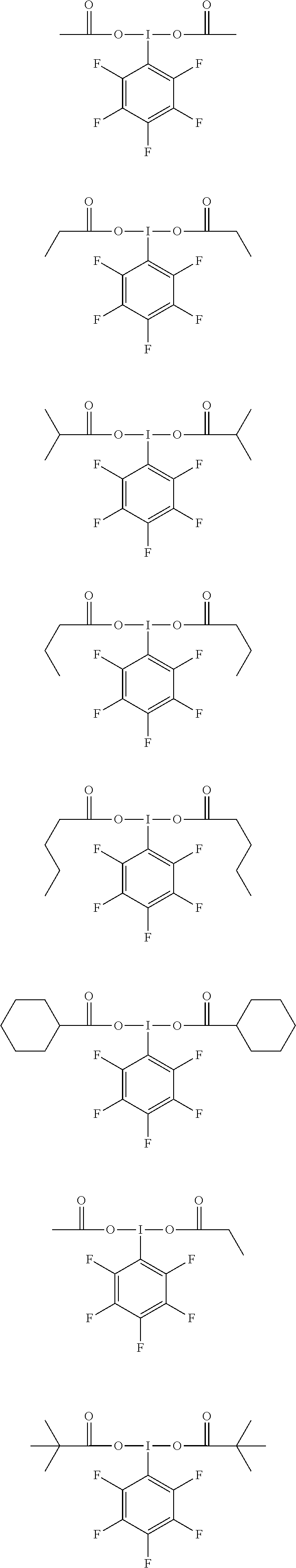

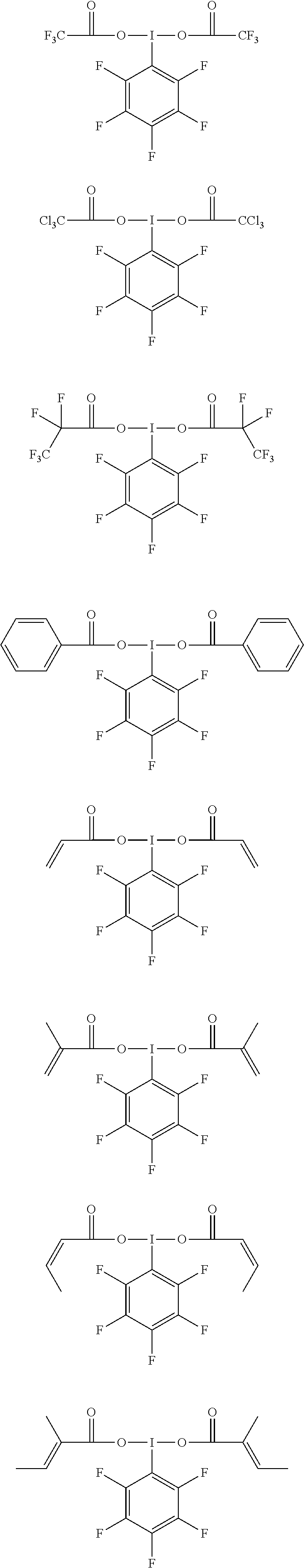

### [Carboxy-Containing Polymer]

The carboxy-containing polymer comprises repeat units having the formula (2), and repeat units of at least one type selected from repeat units having the formula (3), repeat units having the formula (4), repeat units having the formula (5), repeat units having the formula (6), and repeat units having the formula (7).

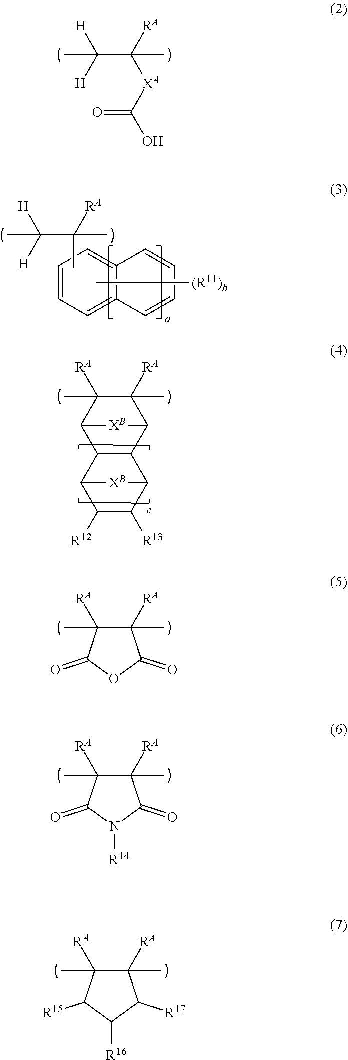

In formulae (2) to (7), R^{A} is hydrogen, fluorine, methyl or trifluoromethyl.

In formulae (2) to (7), X^{A} is a single bond, phenylene, naphthylene, or *—C(═O)—O—X^{A1}—. X^{A1} is a C₁-C₁₀ saturated hydrocarbylene group, phenylene group or naphthylene group, the saturated hydrocarbylene group may contain at least one moiety selected from hydroxy, ether bond, ester bond and lactone ring. The asterisk (*) designates a point of attachment to the carbon atom in the backbone.

In formula (3), a is an integer of 0 to 2, and b is an integer meeting 0≤b≤5+2a.

In formula (3), R¹¹ is hydroxy, halogen, nitro, sulfo, carboxy, isocyanate, a C₁-C₂₀ hydrocarbyl group which may contain a heteroatom, —N(R^{11A})(R^{11B}), —P(R^{11C})(R^{11D}), —B(OR^{11E})(OR^{11F}), —O—R^{11G}, —C(═O)—O—R^{11G}, or —O—C(═O)—R^{11G}. R^{11A} and R^{11B} are each independently hydrogen or a C₁-C₂₀ hydrocarbyl group. R^{11C} and R^{11D} are each independently a C₁-C₂₀ hydrocarbyl group. R^{11E} and R^{11F} are each independently a C₁-C₂₀ hydrocarbyl group. R^{11E} and R^{11F} may bond together to form a ring with the boron atom to which they are attached. R^{11G} is each independently a C₁-C₂₀ hydrocarbyl group which may contain a heteroatom.

In formula (4), c is an integer of 0 to 2.

In formula (4), X^{B} is each independently —CH₂— or —O—.

In formulae (4) and (7), R¹², R¹³, and R¹⁵ to R¹⁷ are each independently hydrogen, halogen, or a C₁-C₂₀ hydrocarbyl group which may contain a heteroatom. R¹² and R¹³ may bond together to form a ring with the carbon atoms to which they are attached. R¹⁵ and R¹⁶ and/or R¹⁶ and R¹⁷ may bond together to form a ring with the carbon atoms to which they are attached.

In formula (6), R¹⁴ is hydrogen or a C₁-C₂₀ hydrocarbyl group which may contain a heteroatom.

Examples of the halogen represented by R¹¹, R¹², R¹³ and R¹⁵ to R¹⁷ include fluorine, chlorine, bromine and iodine.

The hydrocarbyl groups represented by R¹¹ to R¹⁷ and R^{11A} to R^{11G} may be saturated or unsaturated and straight, branched or cyclic. Examples thereof include C₁-C₂₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₂₀ cyclic saturated hydrocarbyl groups such as cyclopentyl, cyclohexyl, cyclopentylmethyl, cyclopentylethyl, cyclopentylbutyl, cyclohexyl-methyl, cyclohexylethyl, cyclohexylbutyl, norbornyl, tricyclo [5.2.1.0^{2,6}]decanyl, and adamantyl; C₂-C₂₀ alkenyl groups such as vinyl and allyl; C₆-C₂₀ aryl groups such as phenyl and naphthyl, and combinations thereof. In the hydrocarbyl groups represented by R¹¹ to R¹⁷ and R^{11G}, some or all hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy moiety, cyano moiety, halogen, carbonyl moiety, ether bond, thioether bond, ester bond, sulfonate ester bond, carbonate bond, carbamate bond, lactone ring, sultone ring, or carboxylic anhydride (—C(═O)—O—C(═O)—)

Examples of the repeat unit having formula (2) are shown below, but not limited thereto. Herein R^{A} is as defined above.

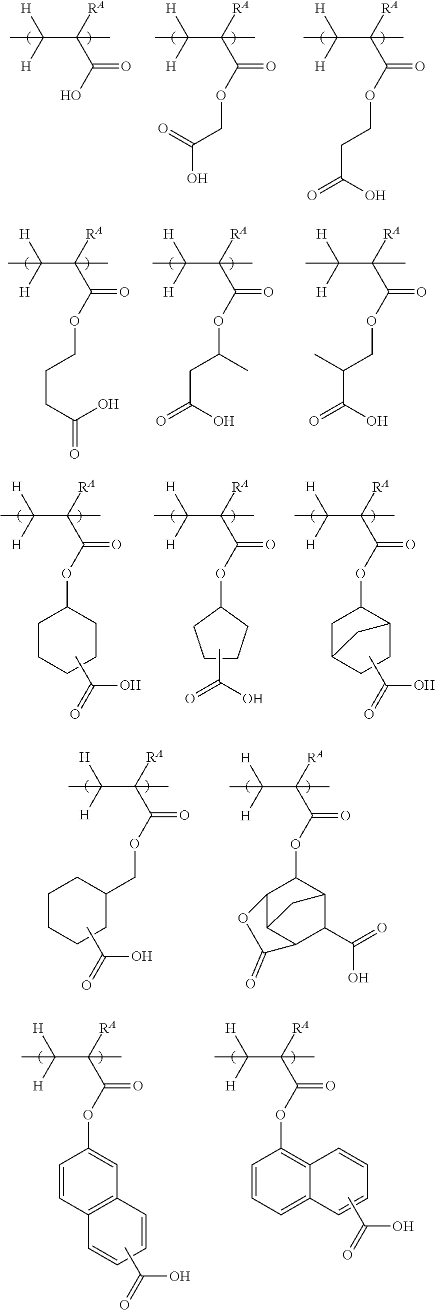

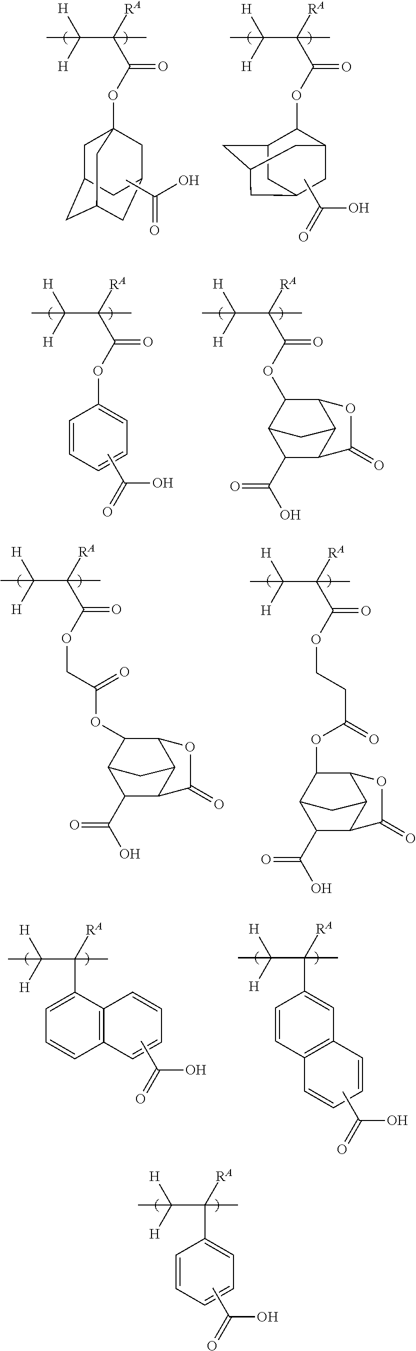

Examples of the repeat unit having formula (3) are shown below, but not limited thereto. Herein R^{A} is as defined above.

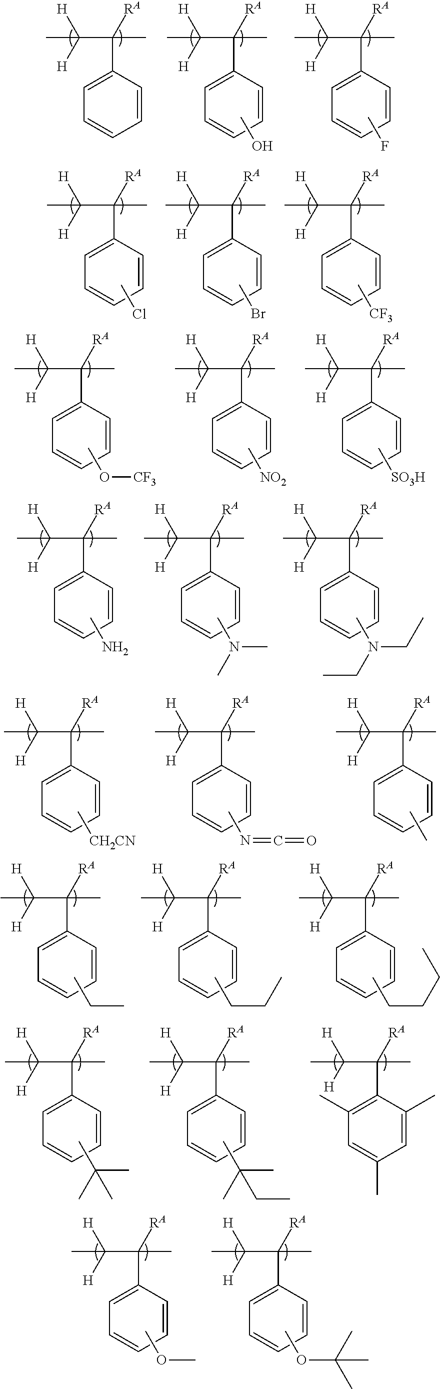

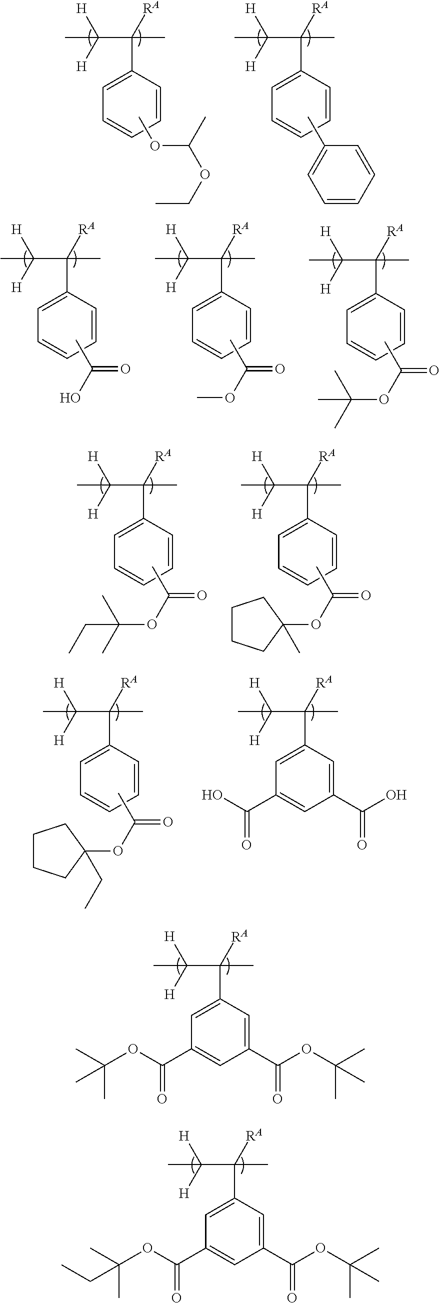

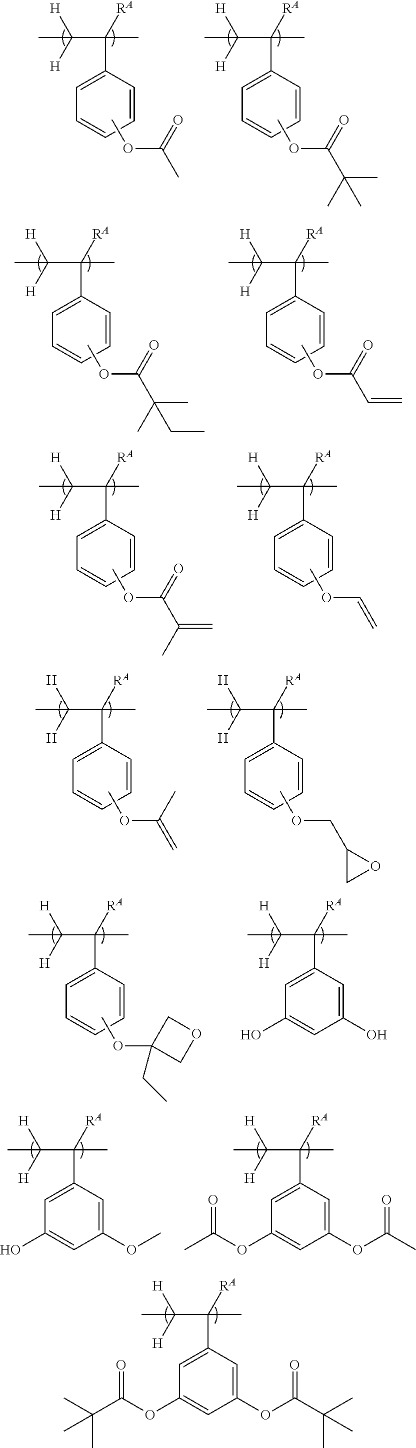

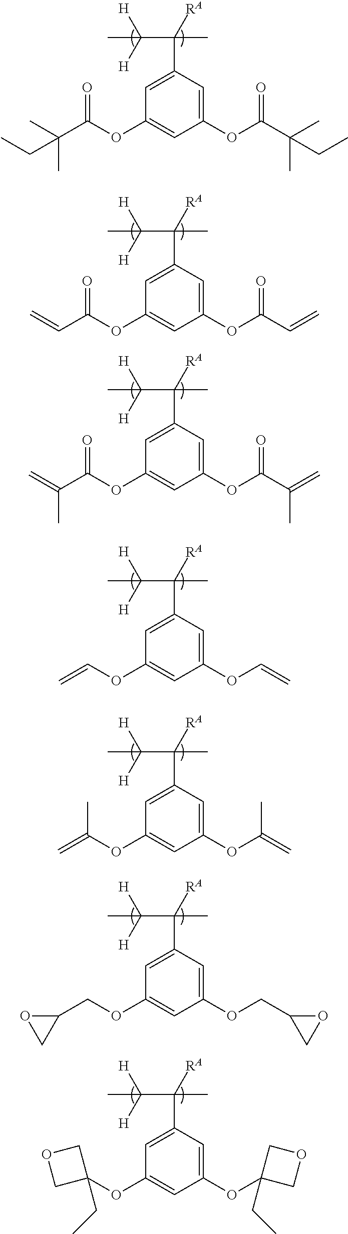

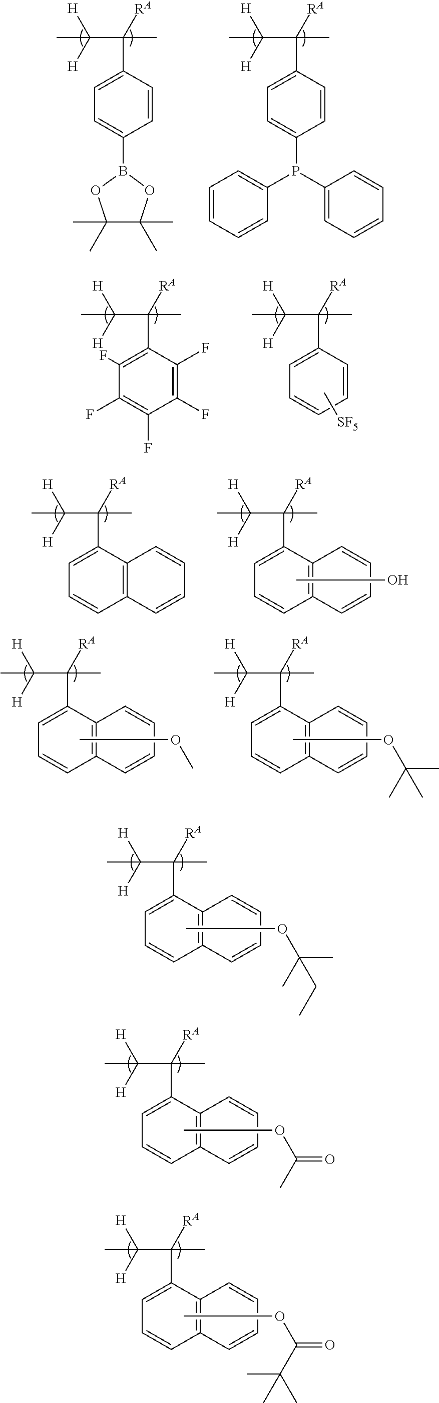

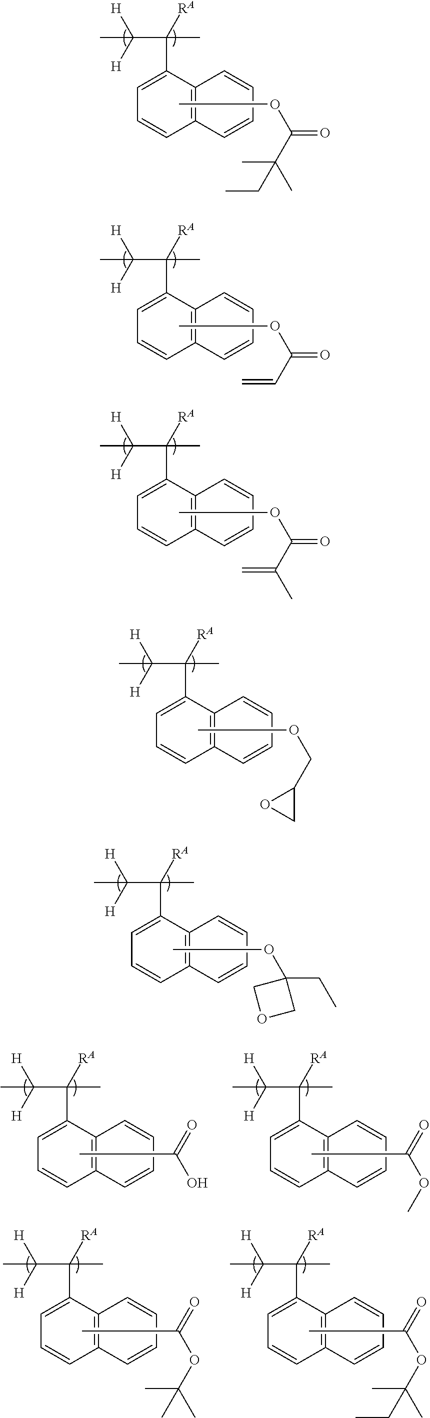

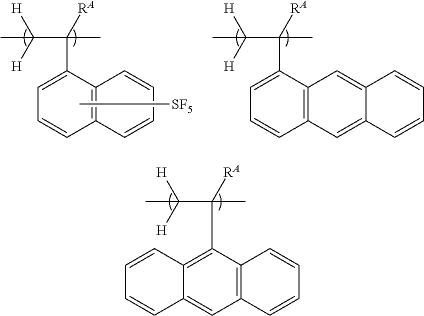

Examples of the repeat unit having formula (4) are shown below, but not limited thereto. Herein R^{A} and X^{B} are as defined above.

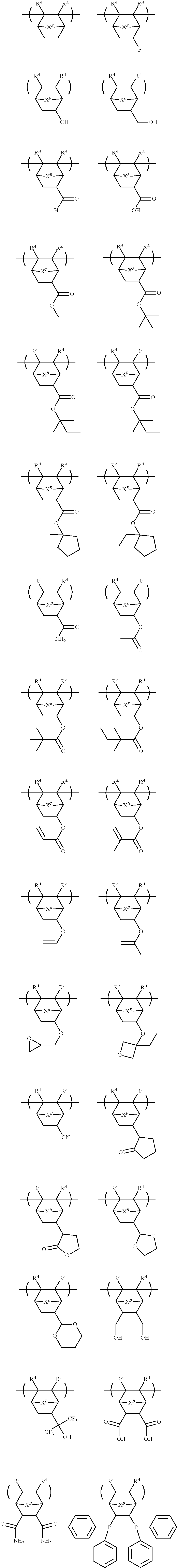

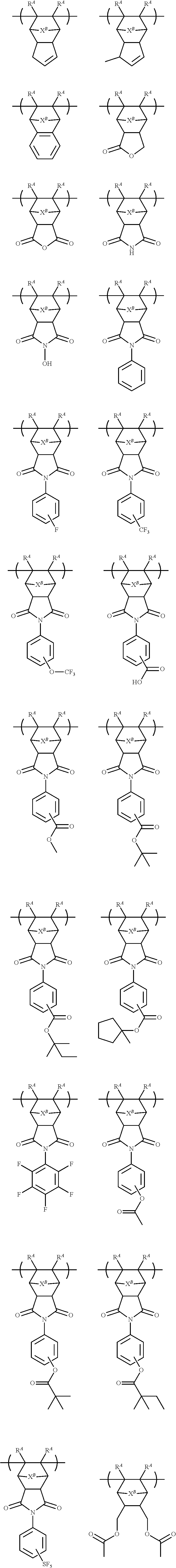

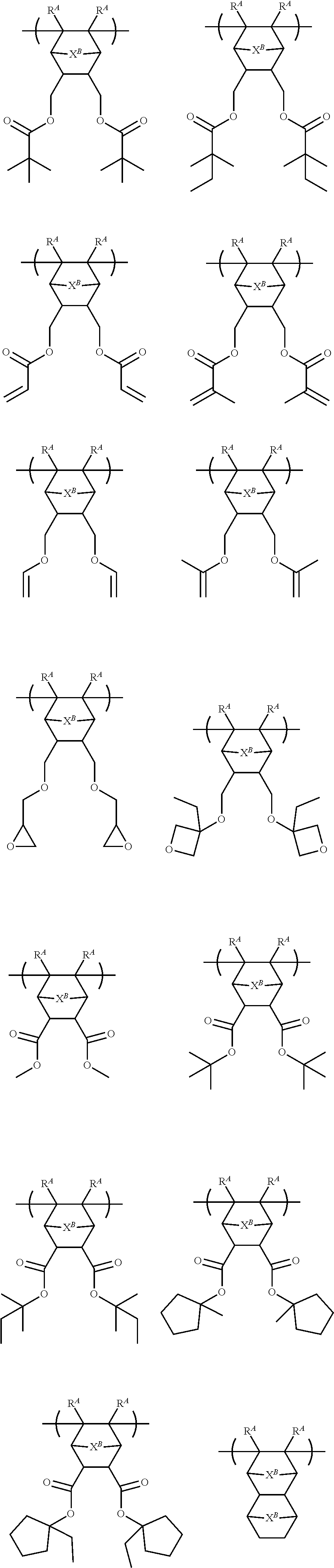

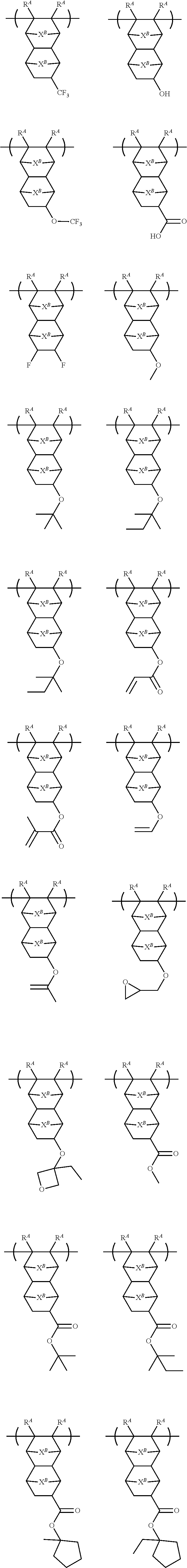

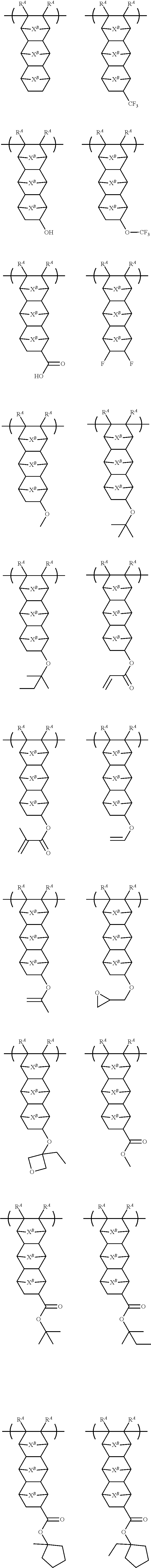

Examples of the repeat unit having formula (6) are shown below, but not limited thereto. Herein R^{A} is as defined above.

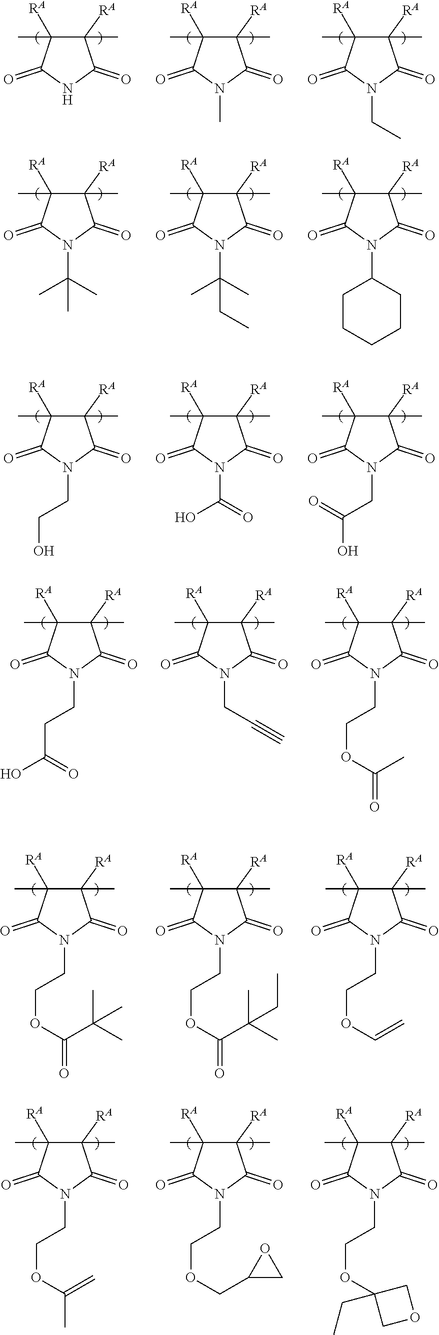

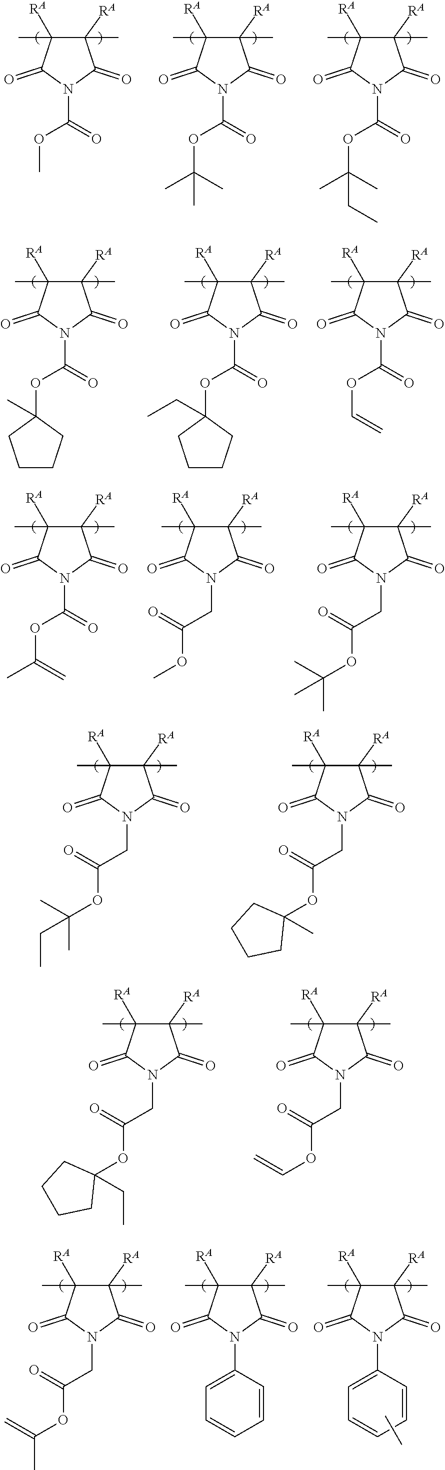

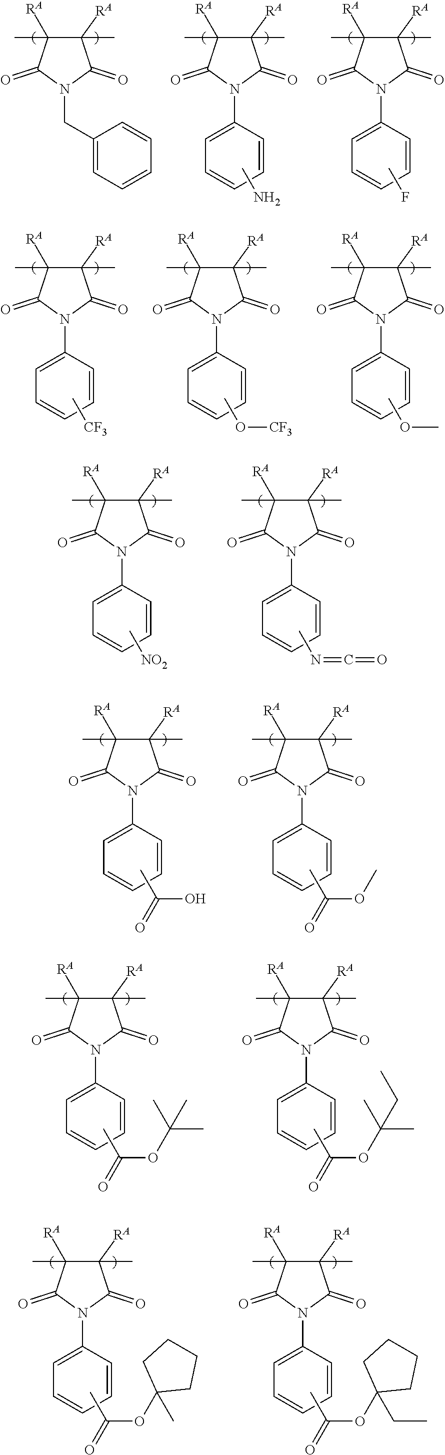

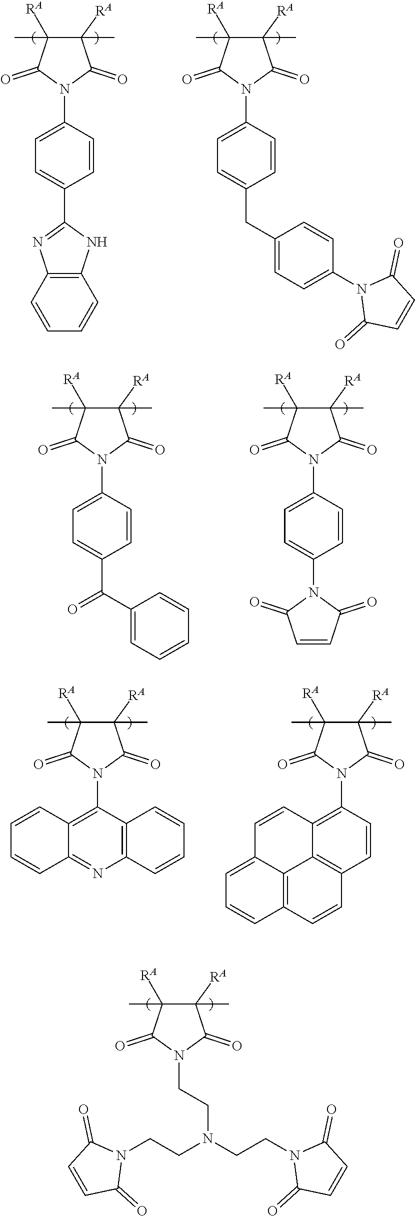

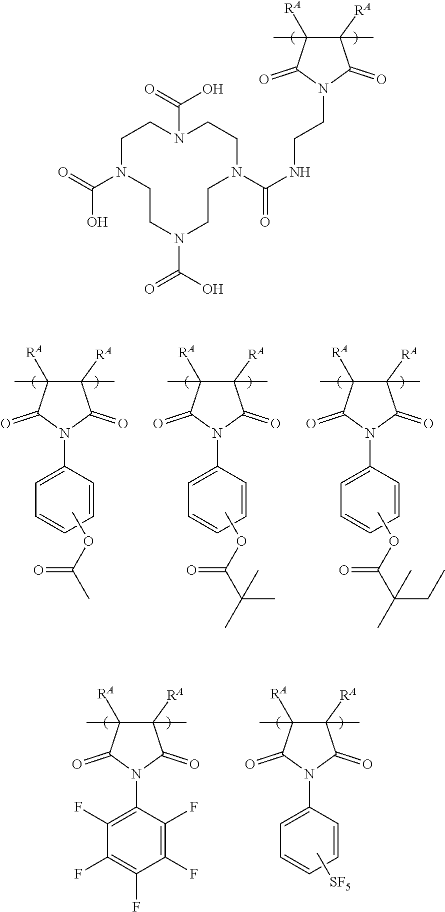

Examples of the repeat unit having formula (7) are shown below, but not limited thereto. Herein R^{A} is as defined above.

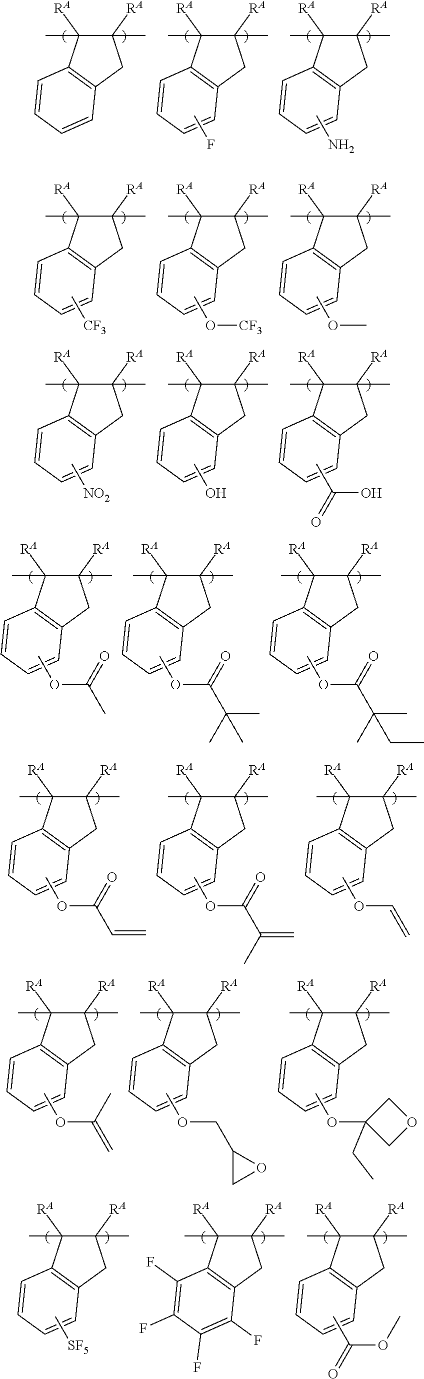

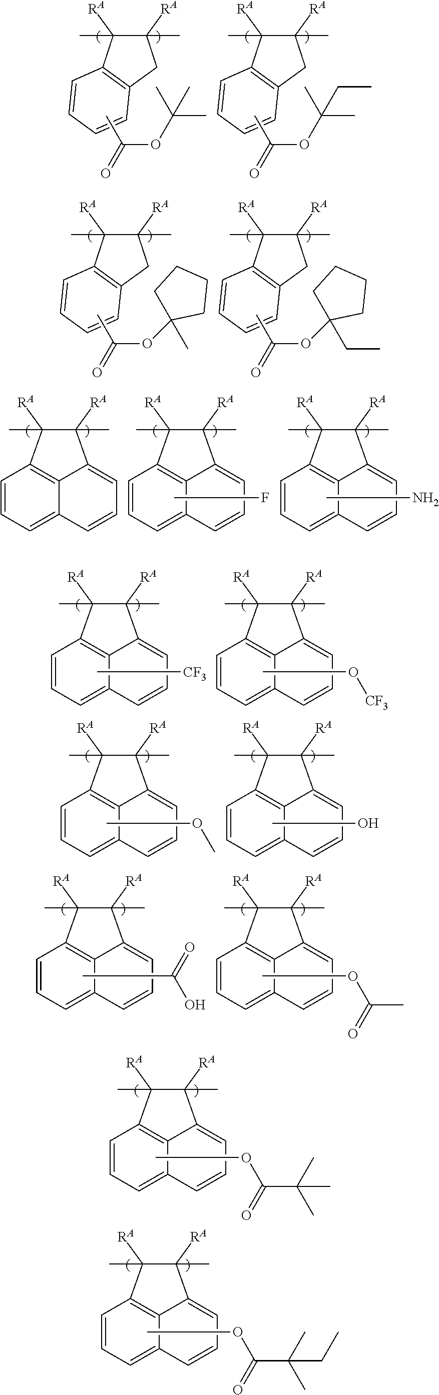

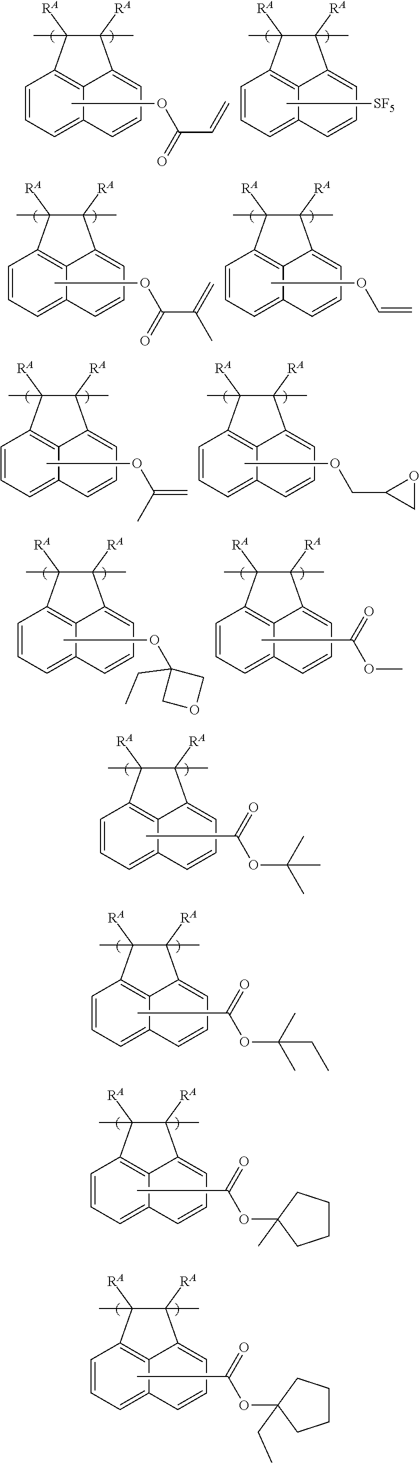

In the carboxy-containing polymer, the molar ratio of repeat units having formula (2) to repeat units other than repeat units having formula (2) is preferably from 10:90 to 90:10, more preferably from 15:85 to 85:15, and even more preferably from 20:80 to 80:20.

The carboxy-containing polymer should preferably have a weight average molecular weight (Mw) in the range of 1,000 to 500,000, and more preferably 3,000 to 100,000, as measured by GPC versus polystyrene standards using tetrahydrofuran (THF) solvent.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the carboxy-containing polymer should preferably have a narrow dispersity (Mw/Mn) of 1.0 to 2.0 in order to provide a resist composition suitable for micropatterning to a small feature size.

The carboxy-containing polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. The amount of the initiator added is preferably 0.01 to 25 mol % of the total of monomers to be polymerized. The reaction temperature is preferably 50 to 150° C., more preferably 60 to 100° C. The reaction time is preferably 2 to 24 hours, more preferably 2 to 12 hours in view of production efficiency.

The polymerization initiator may be added to the monomer solution, which is fed to the reactor. Alternatively, a solution of the polymerization initiator is prepared separately from the monomer solution, and the monomer and initiator solutions are independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

The amount of each monomer in the monomer solution is set such that the content of the corresponding repeat unit may fall in the preferred range.

In the resist composition, the hypervalent iodine compound and the carboxy-containing polymer are preferably present such that the molar ratio of the hypervalent iodine compound to the carboxylic acid-containing repeat unit in the carboxy-containing polymer may range from 10:90 to 90:10, more preferably from 20:80 to 80:20, even more preferably from 30:70 to 70:30. The hypervalent iodine compound may be used alone or as a mixture of two or more compounds having different Mw and/or Mw/Mn. The carboxy-containing polymer may be used alone or as a mixture of two or more polymers having different Mw and/or Mw/Mn.

### [Organic Solvent]

The resist composition further contains a solvent. The solvent is not particularly limited as long as the hypervalent iodine compound, the carboxy-containing polymer and other components are dissolvable therein and a film can be formed from the resulting solution. Organic solvents are preferred. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, and 4-methyl-2-pentanol; ethers such as propylene glycol monomethyl ether, ethylene glycol monomethyl ether, propylene glycol monoethyl ether, ethylene glycol monomethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, and methyl 2-hydroxybutyrate; carboxylic acids such as formic acid, acetic acid, and propionic acid; lactones such as γ-butyronitrile, and mixtures thereof.

The organic solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent.

### [Other Components]

The resist composition may further contain a surfactant as another component. The surfactant is preferably selected from fluorochemical and silicon-based surfactants.

Exemplary surfactants are described, for example, in US 2008/0248425, paragraph [0276]. Also useful are surfactants other than the fluorochemical and silicon-based surfactants, as described, for example, in US 2008/0248425, paragraph [0280]. When used, the surfactant is preferably present in an amount of 0.0001 to 2% by weight based on the overall solids. The surfactant may be used alone or in admixture.

The resist composition may further contain a radical scavenger (or radical trapping agent) as an additional component. When added, the radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol. When used, the radical scavenger is preferably present in an amount of 0.01 to 10% by weight based on the overall solids. The radical scavenger may be used alone or in admixture.

The resist composition contains the hypervalent iodine compound and the carboxy-containing polymer as main components, but not a base polymer containing an acid labile group and a photoacid generator as used in conventional chemically amplified resist compositions. Nevertheless, this resist composition works such that the region thereof exposed to EB or EUV turns soluble in the developer to form a positive tone pattern. Although its mechanism is not well understood, the following mechanism is presumed.

The hypervalent iodine compound is a three-coordinate compound having bonded thereto an aryl group and two carboxylate ligands as represented by formula (1). When such a three-coordinate iodine compound is mixed with a carboxylic acid, replacement of carboxylate ligands takes place as equilibration reaction. If the original carboxylate ligands are removed by any suitable means, a hypervalent iodine compound having new ligands is created. For example, if iodobenzene diacetate which is relatively readily available as the hypervalent iodine compound is mixed with a carboxylic acid having a high molecular weight, and the resulting low-boiling acetic acid is removed, then ligand exchange is completed. When the carboxylic acid is a polymer, polymer molecules are crosslinked by the hypervalent iodine compound to form a high-molecular-weight hypervalent iodine compound.

The polymer crosslinked with the hypervalent iodine compound is formed during film preparation. The reason is that even when such a crosslinked polymer is previously synthesized, the crosslinked polymer is not soluble in almost all solvents so that a solution may not be prepared. If the hypervalent iodine compound having a low solvent solubility because of inherently strong polarization, has taken therein a carboxylic acid-containing polymer, which is a high-molecular-weight compound, as a ligand, then the compound suffers from a further loss of solubility. It is thus desirable that a resist film be formed while ligand exchange reaction be completed by removing the original low-molecular-weight carboxylic acid component during film formation and subsequent bake steps.

The resist film obtained from the inventive resist composition is extremely low in organic solvent solubility because the film contains the polymer crosslinked with the hypervalent iodine compound, which is formed during film formation. However, as the hypervalent iodine compound is decomposed with light, it becomes a monovalent iodine compound. At the same time, the crosslink between polymer molecules is canceled and the molecular weight is reduced. As a result, the film in the exposed region becomes soluble in the organic solvent or developer and the resist composition functions in positive tone.

The polymer used in the resist composition is a copolymer comprising carboxy-containing repeat units having formula (2) and repeat units having any one of formulae (3) to (7). Since the repeat unit having any one of formulae (3) to (7) is a robust unit having a cyclic structure, the polymer exhibits excellent collapse resistance in line-and-space pattern formation and improved etch resistance.

From the foregoing presumption, the inventive resist composition is regarded as falling in the concept of non-chemically-amplified resist composition. There is no need for an acid labile group-containing polymer and a photoacid generator as used in conventional chemically amplified resist compositions. Using the inventive resist composition, a small size pattern can be resolved without any adverse effect (e.g., image blur) due to acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, since the inventive resist composition does not use metal elements, it is advantageous in defectiveness over the metal resist and eliminates the problem of solvent solubility. Using the inventive resist composition, a positive tone pattern is formed without development or through organic solvent development. In the step of forming contact holes, for example, the reversal processing step as conducted in negative tone development is unnecessary. From these aspects, the inventive resist composition is regarded more useful than the metal resist composition.

JP-A 2015-180928 and JP-A 2018-095853 describe a resist composition comprising a hypervalent iodine compound as an additive and a resist composition comprising a base polymer having a hypervalent iodine compound incorporated in its framework. It is described in these patent documents that these resist compositions are successful only in improving line edge roughness. They refer nowhere to a possibility of photo-decomposition of the hypervalent iodine compound and an ability to function as a non-chemically amplified resist. In these resist compositions, the hypervalent iodine compound is not a main component. It is then believed that a material capable of reducing shot noise during the EUV lithography and forming a small size pattern as the non-chemically amplified resist is not conceivable from these patent documents. That is, the present invention provides a definitely novel resist composition and pattern forming process.

### [Pattern Forming Process]

When the resist composition is used in the fabrication of various integrated circuits, any well-known lithography techniques are applicable. For example, the invention provides a pattern forming process comprising the steps of applying the resist composition onto a substrate or a substrate having an underlying film thereon to form a resist film on the substrate or underlying film, exposing the resist film to high-energy radiation, and optionally developing the exposed resist film in a developer.

First, the resist composition is applied onto a substrate for integrated circuit fabrication (e.g., Si, SiO₂, SiN, SiON, TIN, WSi, BPSG, SOG, or organic antireflective coating) or a substrate having an underlying film thereon, or a substrate for mask circuit fabrication (e.g., Cr, CrO, CrON, MoSi₂, or SiO₂) or a substrate having an underlying film thereon by any suitable technique such as spin coating, roll coating, flow coating, dip coating, spray coating or doctor coating. The coating is prebaked (PAB) on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm. Notably, the underlying film refers to a film formed between a substrate and a resist film in the multilayer resist process. The underlying film is not particularly limited and any of well-known films may be used.

Next the resist film is exposed to high-energy radiation. The radiation is selected from among UV, deep UV, EB, EUV, X-ray, soft X-ray, excimer laser radiation, γ-ray, and synchrotron radiation. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 8,000 μC/cm², more preferably about 0.5 to 1,500 μC/cm². The resist composition is best suited in micropatterning using EB or EUV as the high-energy radiation.

If necessary, the resist film is post-exposure baked (PEB). Preferably PEB is performed on a hot plate or in an oven at 30 to 150° C. for 10 seconds to 30 minutes, more preferably at 60 to 120° C. for 30 seconds to 20 minutes.

After the exposure or PEB, the resist film is developed in a developer to form a pattern, if necessary. In the practice of the invention, the exposed region of the resist film is solubilized through organic solvent development to form a positive tone pattern. The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, n-butanol, n-pentanol, formic acid, acetic acid, propionic acid, propyl acetate, butyl acetate, isobutyl acetate, pentyl acetate, isopentyl acetate, butenyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol, 4-methyl-2-pentanol, toluene, anisole and xylene. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight.

### [1] Synthesis of Polymers

Polymers were synthesized using the monomers shown below.

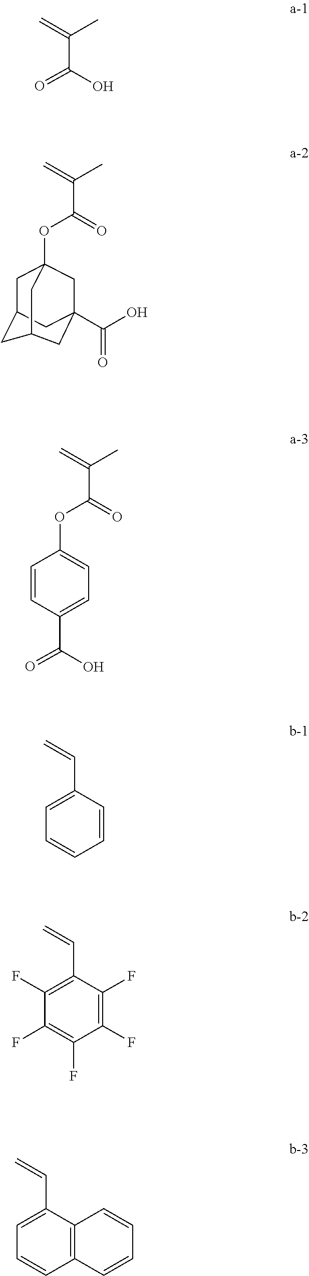

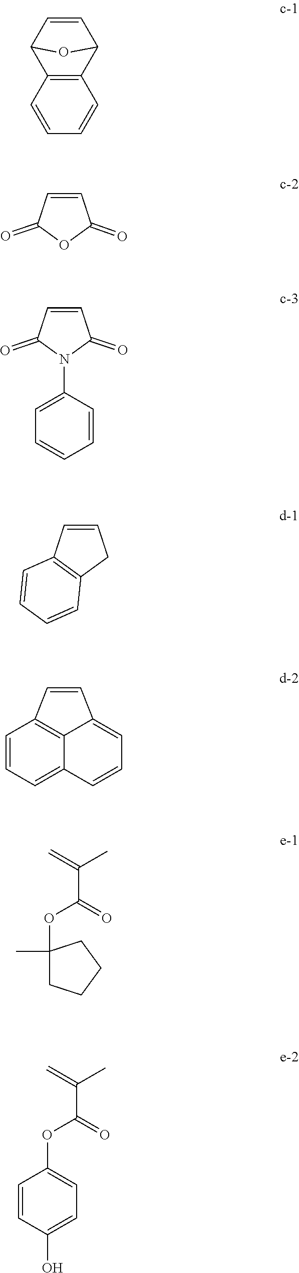

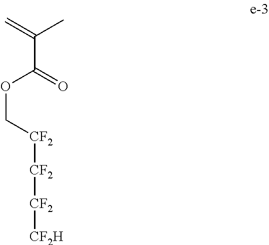 [SMILES: C=C(C)C(=O)OCC(F)(F)C(F)(F)C(F)(F)C(F)F]

### [Synthesis Example 1] Synthesis of Polymer P-1

In nitrogen atmosphere, a flask was charged with 56 g of Monomer a-1, 36 g of Monomer b-1, 5.4 g of dimethyl 2,2′-azobis(isobutyrate) (V-601, FUJIFILM Wako Pure Chemical Corp.), and 180 g of methyl ethyl ketone (MEK) to form a monomer/initiator solution. Another flask in nitrogen atmosphere was charged with 55 g of MEK and heated at 80° C. with stirring, after which the monomer/initiator solution was added dropwise over 4 hours. After the completion of dropwise addition, the polymerization solution was continuously stirred for 2 hours while keeping the temperature of 80° C. It was then cooled to room temperature. With vigorous stirring, the polymerization solution was added dropwise to 4,000 g of hexane whereupon a polymer precipitated. The polymer was collected by filtration, washed twice with 1,200 g of hexane, and vacuum dried at 50° C. for 20 hours, obtaining the polymer P-1 in white powder form. Amount 90 g and yield 98%. Polymer P-1 had a Mw of 8,000 and a Mw/Mn of 1.42 as measured by GPC versus polystyrene standards using THF solvent.

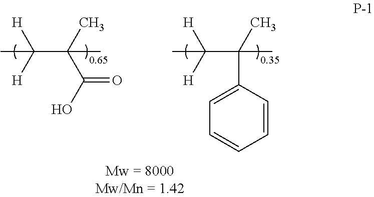

### [Synthesis Examples 2 to 26] Synthesis of Polymers P-2 to P-26

Polymers (Polymers P-2 to P-26) shown in Table 1 were prepared by the same procedure as in Synthesis Example 1 except that the type and amount of monomers used were changed.

TABLE 1

| | | Incorporation | | Incorporation | | |
|---|---|---|---|---|---|---|
| Polymer | Unit 1 | ratio (mol %) | Unit 2 | ratio (mol %) | Mw | Mw/Mn |
| P-1 | a-1 | 65 | b-1 | 35 | 8,000 | 1.42 |
| P-2 | a-1 | 50 | b-2 | 50 | 8,400 | 1.51 |
| P-3 | a-1 | 60 | b-3 | 40 | 8,100 | 1.42 |
| P-4 | a-1 | 65 | c-1 | 35 | 7,900 | 1.44 |
| P-5 | a-1 | 50 | c-2 | 50 | 8,300 | 1.43 |
| P-6 | a-1 | 60 | c-3 | 40 | 8,200 | 1.46 |
| P-7 | a-1 | 65 | d-1 | 35 | 7,000 | 1.46 |
| P-8 | a-1 | 50 | d-2 | 50 | 7,100 | 1.46 |
| P-9 | a-2 | 65 | b-1 | 35 | 8,000 | 1.44 |
| P-10 | a-2 | 50 | b-2 | 50 | 8,600 | 1.41 |
| P-11 | a-2 | 60 | b-3 | 40 | 7,900 | 1.49 |
| P-12 | a-2 | 65 | c-1 | 35 | 9,800 | 1.45 |
| P-13 | a-2 | 50 | c-2 | 50 | 7,600 | 1.47 |
| P-14 | a-2 | 60 | c-3 | 40 | 8,500 | 1.42 |
| P-15 | a-2 | 65 | d-1 | 35 | 7,000 | 1.46 |
| P-16 | a-2 | 65 | d-2 | 35 | 7,100 | 1.46 |
| P-17 | a-3 | 65 | b-1 | 35 | 9,400 | 1.40 |
| P-18 | a-3 | 50 | b-2 | 50 | 9,000 | 1.45 |
| P-19 | a-3 | 60 | b-3 | 40 | 7,500 | 1.46 |
| P-20 | a-3 | 65 | c-1 | 35 | 7,000 | 1.48 |
| P-21 | a-3 | 50 | c-2 | 50 | 8,200 | 1.49 |
| P-22 | a-3 | 60 | c-3 | 40 | 8,800 | 1.47 |
| P-23 | a-3 | 65 | d-1 | 35 | 7,000 | 1.46 |
| P-24 | a-3 | 65 | d-2 | 35 | 7,100 | 1.46 |
| P-25 | a-1 | 65 | e-3 | 35 | 8,100 | 1.40 |
| P-26 | e-1 | 60 | e-2 | 40 | 8,500 | 1.45 |

### [2] Preparation of Resist Composition

### Examples 1-1 to 1-26 and Comparative Examples 1-1 to 1-3

Resist compositions (R-01 to R-26 and CR-01) were prepared by dissolving a hypervalent iodine compound and a polymer in a solvent containing 0.01 wt % of a surfactant (PF-636, Omnova Solutions, Inc.) in accordance with the recipe shown in Table 2, and filtering the solution through a Teflon® filter having a pore size of 0.2 μm. Also, resist compositions (CR-02 and CR-03) were prepared by dissolving a polymer, a photoacid generator, and a sensitivity modifier in a solvent containing 0.01 wt % of a surfactant (PF-636, Omnova Solutions, Inc.) in accordance with the recipe shown in Table 3, and filtering the solution through a Teflon® filter having a pore size of 0.2 μm.

TABLE 2

| | | Resist | Hypervalent iodine | Polymer | Solvent 1 | Solvent 2 |
|---|---|---|---|---|---|---|
| | | composition | compound (pbw) | (pbw) | (pbw) | (pbw) |
| Example | 1-1 | R-01 | I-1 (10) | P-1 (9) | PGMEA (800) | AcOH (200) |
| | 1-2 | R-02 | I-2 (13) | P-1 (9) | PGMEA (800) | AcOH (200) |
| | 1-3 | R-03 | I-3 (11) | P-1 (9) | PGMEA (800) | AcOH (200) |
| | 1-4 | R-04 | I-1 (10) | P-2 (17) | PGMEA (800) | AcOH (200) |
| | 1-5 | R-05 | I-1 (10) | P-3 (11) | PGMEA (800) | AcOH (200) |
| | 1-6 | R-06 | I-1 (10) | P-4 (10) | PGMEA (800) | AcOH (200) |
| | 1-7 | R-07 | I-1 (10) | P-5 (11) | PGMEA (800) | AcOH (200) |
| | 1-8 | R-08 | I-1 (10) | P-6 (9) | PGMEA (800) | AcOH (200) |
| | 1-9 | R-09 | I-1 (10) | P-7 (9) | PGMEA (800) | AcOH (200) |
| | 1-10 | R-10 | I-1 (10) | P-8 (11) | PGMEA (800) | AcOH (200) |
| | 1-11 | R-11 | I-1 (10) | P-9 (19) | PGMEA (800) | AcOH (200) |
| | 1-12 | R-12 | I-1 (10) | P-10 (28) | PGMEA (800) | AcOH (200) |
| | 1-13 | R-13 | I-1 (10) | P-11 (22) | PGMEA (800) | AcOH (200) |
| | 1-14 | R-14 | I-1 (10) | P-12 (20) | PGMEA (800) | AcOH (200) |
| | 1-15 | R-15 | I-1 (10) | P-13 (22) | PGMEA (800) | AcOH (200) |
| | 1-16 | R-16 | I-1 (10) | P-14 (23) | PGMEA (800) | AcOH (200) |
| | 1-17 | R-17 | I-2 (13) | P-15 (20) | PGMEA (800) | AcOH (200) |
| | 1-18 | R-18 | I-3 (11) | P-16 (21) | PGMEA (800) | AcOH (200) |
| | 1-19 | R-19 | I-1 (10) | P-17 (12) | PGMEA (800) | AcOH (200) |
| | 1-20 | R-20 | I-1 (10) | P-18 (21) | PGMEA (800) | AcOH (200) |
| | 1-21 | R-21 | I-1 (10) | P-19 (15) | PGMEA (800) | AcOH (200) |
| | 1-22 | R-22 | I-1 (10) | P-20 (14) | PGMEA (800) | AcOH (200) |
| | 1-23 | R-23 | I-1 (10) | P-21 (15) | PGMEA (800) | AcOH (200) |
| | 1-24 | R-24 | I-1 (10) | P-22 (16) | PGMEA (800) | AcOH (200) |
| | 1-25 | R-25 | I-1 (10) | P-23 (13) | PGMEA (800) | AcOH (200) |
| | 1-26 | R-26 | I-1 (10) | P-24 (14) | PGMEA (800) | AcOH (200) |
| Comparative | 1-1 | CR-01 | I-1 (10) | P-25 (15) | PGMEA (800) | AcOH (200) |
| Example | | | | | | |

TABLE 3

| | | | | | Sensitivity | | |
|---|---|---|---|---|---|---|---|
| | | Resist | Polymer | PAG | modifier | Solvent 1 | Solvent 2 |
| | | composition | (pbw) | (pbw) | (pbw) | (pbw) | (pbw) |
| Comparative | 1-2 | CR-02 | P-1 (80) | PAG-1 (19) | Q-1 (6) | PGMEA (1890) | GBL (210) |
| Example | 1-3 | CR-03 | P-1 (80) | PAG-1 (19) | I-1 (5) | PGMEA (1890) | GBL (210) |

In Tables 2 and 3, the hypervalent iodine compound (I-1 to I-3), photoacid generator (PAG-1), sensitivity modifier (Q-1), and solvent are identified below.

### Hypervalent Iodine Compounds: I-1 to I-3

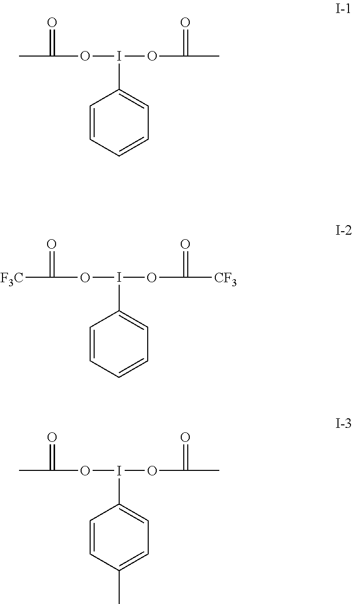

### Photoacid Generator: PAG-1

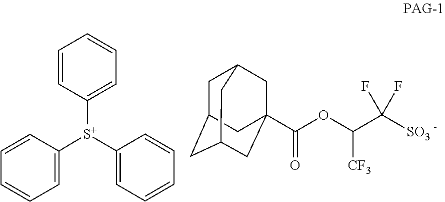

### Sensitivity Modifier: Q-1

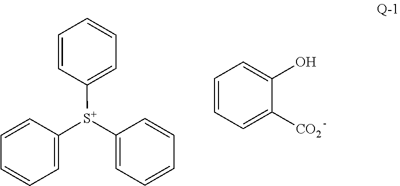

### Solvents:

PGMEA (propylene glycol monomethyl ether acetate)
AcOH (acetic acid)
GBL (γ-butyrolactone)

### [3] EUV Lithography Test 1

### Examples 2-1 to 2-26 and Comparative Examples 2-1 to 2-3

Each of the resist compositions (R-01 to R-26, CR-01 to CR-03) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 4 for 60 seconds to form a resist film of 40 nm thick. Using an EUV scanner NXE3400 (ASML, NA 0.33, σ 0.9, 90° dipole illumination), the resist film was exposed to EUV through a mask bearing a 36-nm 1:1 line-and-space (LS) pattern. The resist film was baked (PEB) on a hotplate at the temperature shown in Table 4 for 60 seconds and developed in the developer shown in Table 4 for 30 seconds to form a LS pattern having a space width of 18 nm and a pitch of 36 nm.

The LS pattern was observed under CD-SEM (CG-6300, Hitachi High-Technologies Corp.) and evaluated for sensitivity, LWR and maximum resolution by the following methods. The results are shown in Table 4.

### [Evaluation of Sensitivity]

The optimum dose (Eop, mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 4

| | | Resist | PAB/PEB | | Eop | LWR | Maximum |
|---|---|---|---|---|---|---|---|
| | | composition | (° C.) | Developer | (mJ/cm²) | (nm) | resolution (nm) |
| Example | 2-1 | R-01 | 110/90 | nBA | 45 | 3.5 | 12 |
| | 2-2 | R-02 | 110/90 | nBA | 44 | 3.8 | 14 |
| | 2-3 | R-03 | 110/90 | nBA | 42 | 3.8 | 14 |
| | 2-4 | R-04 | 110/90 | nBA | 40 | 3.6 | 12 |
| | 2-5 | R-05 | 110/90 | nBA | 44 | 3.7 | 13 |
| | 2-6 | R-06 | 110/90 | nBA | 45 | 3.8 | 14 |
| | 2-7 | R-07 | 110/90 | nBA | 44 | 3.5 | 13 |
| | 2-8 | R-08 | 110/90 | nBA | 45 | 3.8 | 13 |
| | 2-9 | R-09 | 110/90 | nBA | 40 | 3.8 | 14 |
| | 2-10 | R-10 | 110/90 | nBA | 42 | 3.8 | 14 |
| | 2-11 | R-11 | 110/90 | nBA | 42 | 3.7 | 14 |
| | 2-12 | R-12 | 110/90 | nBA | 40 | 3.8 | 14 |
| | 2-13 | R-13 | 110/90 | nBA | 45 | 3.6 | 13 |
| | 2-14 | R-14 | 110/90 | nBA | 45 | 3.6 | 12 |
| | 2-15 | R-15 | 110/90 | nBA | 42 | 3.8 | 14 |
| | 2-16 | R-16 | 110/90 | nBA | 40 | 3.8 | 14 |
| | 2-17 | R-17 | 110/90 | nBA | 40 | 3.6 | 13 |
| | 2-18 | R-18 | 110/90 | nBA | 40 | 3.6 | 14 |
| | 2-19 | R-19 | 110/90 | nBA | 40 | 3.8 | 13 |
| | 2-20 | R-20 | 110/90 | nBA | 40 | 3.6 | 13 |
| | 2-21 | R-21 | 110/90 | nBA | 40 | 3.6 | 14 |
| | 2-22 | R-22 | 110/90 | nBA | 40 | 3.8 | 13 |
| | 2-23 | R-23 | 110/90 | nBA | 40 | 3.6 | 14 |
| | 2-24 | R-24 | 110/90 | nBA | 40 | 3.6 | 14 |
| | 2-25 | R-25 | 110/90 | nBA | 40 | 3.8 | 14 |
| | 2-26 | R-26 | 110/90 | nBA | 40 | 3.6 | 14 |
| Comparative | 2-1 | CR-01 | 110/90 | nBA | 39 | 3.6 | 14 |
| Example | 2-2 | CR-02 | 105/90 | TMAH | 85 | 4.8 | 18 |
| | 2-3 | CR-03 | 105/90 | TMAH | 85 | 4.8 | 18 |

In the developer column, nBA stands for n-butyl acetate and TMAH for a 2.38 wt % tetramethylammonium hydroxide aqueous solution.

It is evident from Table 4 that the resist compositions within the scope of the invention form LS patterns having satisfactory sensitivity, LWR and resolution when processed by the EUV lithography.

### [4] EUV Lithography Test 2

### Examples 3-1 to 3-26 and Comparative Examples 3-1 to 3-3

Each of the resist compositions (R-01 to R-26, CR-01 to CR-03) was spin coated on a silicon substrate having a 20-nm coating of silicon-containing spin-on hard mask SHB-A940 (Shin-Etsu Chemical Co., Ltd., a silicon content of 43 wt %) and baked (PAB) on a hotplate at the temperature shown in Table 5 for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 5 for 30 seconds to form a hole pattern having a size of 32 nm.

The hole pattern was observed under CD-SEM (CG-6300, Hitachi High-Technologies Corp.) and evaluated for sensitivity, CDU and maximum resolution by the following methods. The results are shown in Table 5.

### [Evaluation of Sensitivity]

The optimum dose (Eop, mJ/cm²) which provided a hole pattern with a size of 22 nm was determined and reported as sensitivity.

### [Evaluation of CDU]

The size of 50 holes which were printed at Eop was measured, from which a 3-fold value (3σ) of the standard deviation (σ) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 5

| | | Resist | PAB/PEB | | Eop | CDU | Maximum |
|---|---|---|---|---|---|---|---|
| | | composition | (° C.) | Developer | (mJ/cm²) | (nm) | resolution (nm) |
| Example | 3-1 | R-01 | 110/90 | nBA | 28 | 2.5 | 24 |
| | 3-2 | R-02 | 110/90 | nBA | 27 | 2.8 | 26 |
| | 3-3 | R-03 | 110/90 | nBA | 25 | 2.9 | 26 |
| | 3-4 | R-04 | 110/90 | nBA | 22 | 2.7 | 25 |
| | 3-5 | R-05 | 110/90 | nBA | 27 | 2.7 | 25 |
| | 3-6 | R-06 | 110/90 | nBA | 28 | 2.9 | 26 |
| | 3-7 | R-07 | 110/90 | nBA | 27 | 2.9 | 25 |
| | 3-8 | R-08 | 110/90 | nBA | 28 | 2.9 | 24 |
| | 3-9 | R-09 | 110/90 | nBA | 22 | 2.7 | 26 |
| | 3-10 | R-10 | 110/90 | nBA | 25 | 2.9 | 26 |
| | 3-11 | R-11 | 110/90 | nBA | 25 | 2.9 | 26 |
| | 3-12 | R-12 | 110/90 | nBA | 22 | 2.6 | 26 |
| | 3-13 | R-13 | 110/90 | nBA | 25 | 2.7 | 25 |
| | 3-14 | R-14 | 110/90 | nBA | 25 | 2.5 | 24 |
| | 3-15 | R-15 | 110/90 | nBA | 23 | 2.8 | 25 |
| | 3-16 | R-16 | 110/90 | nBA | 22 | 2.8 | 25 |
| | 3-17 | R-17 | 110/90 | nBA | 22 | 2.7 | 26 |
| | 3-18 | R-18 | 110/90 | nBA | 22 | 2.7 | 24 |
| | 3-19 | R-19 | 110/90 | nBA | 23 | 2.8 | 25 |
| | 3-20 | R-20 | 110/90 | nBA | 22 | 2.8 | 25 |
| | 3-21 | R-21 | 110/90 | nBA | 25 | 2.7 | 26 |
| | 3-22 | R-22 | 110/90 | nBA | 24 | 2.7 | 25 |
| | 3-23 | R-23 | 110/90 | nBA | 22 | 2.8 | 25 |
| | 3-24 | R-24 | 110/90 | nBA | 22 | 2.8 | 25 |
| | 3-25 | R-25 | 110/90 | nBA | 25 | 2.7 | 26 |
| | 3-26 | R-26 | 110/90 | nBA | 24 | 2.7 | 26 |
| Comparative | 3-1 | CR-01 | 110/90 | nBA | 24 | 2.7 | 26 |
| Example | 3-2 | CR-02 | 105/90 | TMAH | 42 | 3.8 | 32 |
| | 3-3 | CR-03 | 105/90 | TMAH | 40 | 4.0 | 32 |

It is evident from Table 5 that the resist compositions within the scope of the invention form contact hole patterns having satisfactory sensitivity, CDU and resolution when processed by the EUV lithography.

Japanese Patent Application No. 2024-013007 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a hypervalent iodine compound, a carboxy-containing polymer, and a solvent,
the hypervalent iodine compound having the formula (1): 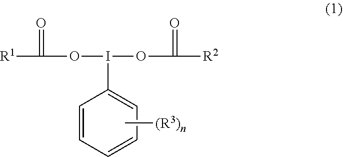
wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and the intervenient atoms, and
R³ is halogen or a C₁-C₄₀ hydrocarbyl group which may contain a heteroatom,
the carboxy-containing polymer comprising repeat units having the formula (2), and repeat units of at least one type selected from repeat units having the formula (3), repeat units having the formula (4), repeat units having the formula (5), repeat units having the formula (6), and repeat units having the formula (7): 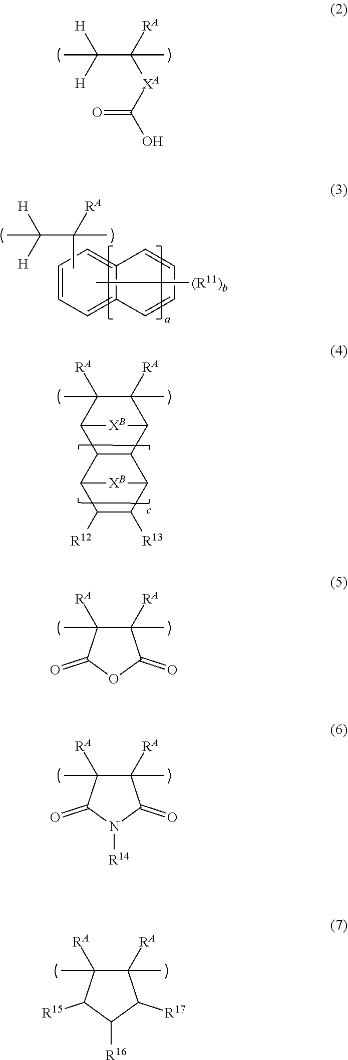
wherein a is an integer of 0 to 2, b is an integer meeting 0≤b≤5+2a, c is an integer of 0 to 2,
R^{A} is hydrogen, fluorine, methyl or trifluoromethyl,
X^{A} is a single bond, phenylene, naphthylene, or*—C(═O)—O—X^{A1}—, X^{A1} is a C₂-C₁₀ saturated hydrocarbylene group, phenylene group or naphthylene group, the saturated hydrocarbylene group may contain at least one moiety selected from hydroxy, ether bond, ester bond and lactone ring, * designates a point of attachment to the carbon atom in the backbone,
X^{B} is each independently —CH₂— or —O—,
R¹¹ is hydroxy, halogen, nitro, sulfo, carboxy, isocyanate, a C₁-C₂₀ hydrocarbyl group which may contain a heteroatom, —N(R^{11A})(R^{11B}), —P(R^{11C})(R^{11D}), —B(OR^{11E})(OR^{11F}), —O—R^{11G}, —C(═O)—O—R^{11G}, or —O—C(═O)—R^{11G}, R^{11A} and R^{11B} are each independently hydrogen or a C₁-C₂₀ hydrocarbyl group, R^{11C} and R^{11D} are each independently a C₁-C₂₀ hydrocarbyl group, R^{11E} and R^{11F} are each independently a C₁-C₂₀ hydrocarbyl group, R^{11E} and R^{11F} may bond together to form a ring with the boron atom to which they are attached, R^{11G} is each independently a C₁-C₂₀ hydrocarbyl group which may contain a heteroatom,
R¹², R¹³, and R¹⁵ to R¹⁷ are each independently hydrogen, halogen, or a C₁-C₂₀ hydrocarbyl group which may contain a heteroatom, R¹² and R¹³ may bond together to form a ring with the carbon atoms to which they are attached, and R¹⁵ and R¹⁶ and/or R¹⁶ and R¹⁷ may bond together to form a ring with the carbon atoms to which they are attached, and
R¹⁴ is hydrogen or a C₁-C₂₀ hydrocarbyl group which may contain a heteroatom.

2. A laminate comprising a substrate and a resist film formed thereon from the resist composition of claim 1.

3. The laminate of claim 2, further comprising an underlying film between the substrate and the resist film.

4. A pattern forming process comprising the steps of applying the resist composition of claim 1 onto a substrate or a substrate having an underlying film deposited thereon to form a resist film thereon, exposing the resist film to i-line, KrF excimer laser, ArF excimer laser, EB or EUV, and developing the exposed resist film in a developer.

5. The pattern forming process of claim 4 wherein the developer is an organic solvent.
